(19) United States
(12) Patent Application Publication
(10) Pub. No.: US 2008/0001642 A1
(43) Pub. Date: Jan. 3, 2008

(54) DELAY-LOCKED LOOP APPARATUS ADJUSTING INTERNAL CLOCK SIGNAL IN SYNCHRONIZATION WITH EXTERNAL CLOCK SIGNAL

(76) Inventors: Won Joo YUN, Seoul (KR); Hyun Woo LEE, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 11/683,528

(22) Filed: Mar. 8, 2007

(30) Foreign Application Priority Data
Jun. 30, 2006 (KR) 10-2006-0061544

(51) Int. Cl. H03L 7/00

(52) U.S. Cl. 327/161

(57) ABSTRACT

A delay-locked loop apparatus includes at least a rising-clock delay-locked circuit, a falling-clock delay-locked circuit, and a duty cycle compensation circuit. The rising-clock delay-locked circuit detects the phase difference between a first clock inputted as a reference clock and a second clock obtained by replica-delaying the first clock, and then delay-locks the first clock and outputs a rising clock. The falling-clock delay-locked circuit detects the phase difference between an inverted clock of the first clock and the rising clock after a delay locking operation with respect to the rising clock, delay-locks an inverted clock of the first clock and outputs a falling clock. The duty cycle compensation circuit compensates duty cycles of the delay-locked rising clock and falling clock, and the falling-clock delay-locked circuit includes a divider for separately dividing the inverted clock and the delay-locked rising clock.

### CROSS-REFERENCE TO RELATED APPLICATIONS

The present application claims priority to Korean patent application number 10-2006-0061544 filed on Jun. 30, 2006, which is incorporated herein by reference in its entirety.

### BACKGROUND OF THE INVENTION

The present invention relates to a delay-locked loop apparatus, and more particularly to a delay-locked loop apparatus that is applied to a synchronous memory device and adjusts the delay of an internal clock signal such that the internal clock signal is synchronized with an external clock signal.

As generally known in the art, a delay-locked loop (DLL) apparatus is used to delay an internal clock of a synchronous memory device using clocks such that the internal clock can be synchronized with an external clock without error (i.e., “skew”). It is noted that “clock signal” is also referred to as “clock” in this disclosure. That is, when an externally inputted clock is used in a semiconductor memory device, a skew may occur between the external clock and the generated internal clock or between the external clock and the data signal. A DLL apparatus reduces a skew between clocks and signals.

The DLL apparatus includes, as shown in FIG. 1, a buffer unit 100, a first replica delay unit 110, a first phase detector 120, a second replica delay unit 130, a second phase detector 140, a delay line unit 150 and a duty cycle compensation unit 160.

In detail, the buffer unit 100 receives and buffers an external clock “CLK,” and outputs the external clock “CLK” as an input clock.

The first replica delay unit 110 receives the input clock processed through the delay line unit 150 and duty cycle compensation unit 160 in an initialized state, performs a replica delay operation on the inputted signal, and then outputs a first delayed clock “DCLK1.”

The first phase detector 120 compares the phase of the external clock “CLK” with the phase of the first delayed clock “DCLK1,” and generates a first detection signal “PD1.”

The second replica delay unit 130 receives the inverted signal of the input clock passed through the delay line unit 150 and duty cycle compensation unit 160 in an initialized state, performs a replica delay operation on the inputted signal, and then outputs a second delayed clock “DCLK2.”

The second phase detector 140 compares the phase of the external clock “CLK” with the phase of the second delayed clock “DCLK2,” and generates a second detection signal “PD2.”

The delay line unit 150 receives the input clock from the buffer unit 100, delays the input clock by a predetermined time period using the first and second detection signals “PD1” and “PD2” provided from the first and second phase detectors 120 and 140, and outputs a rising clock “RCLK” and a falling clock “FCLK.”

The duty cycle compensation unit 160 receives the rising clock “RCLK” and the falling clock “FCLK” from the delay line unit 150, and compensates the duty cycles of the rising clock “RCLK” and falling clock “FCLK,” thereby outputting the output clock “CLK_OUT.”

The DLL apparatus constructed in such a manner adjusts the degree of delay established in the delay line unit 150 by using the first and second detection signals “PD1” and “PD2,” to align the rising edges of the rising clock “RCLK” and falling clock “FCLK.” The DLL apparatus then compensates the duty cycles of the rising clock “RCLK” and falling clock “FCLK” through the duty cycle compensation unit 160.

Before a duty cycle is compensated, both the first and second replica delay units 110 and 130 operate to align the rising edges of the rising clock “RCLK” and falling clock “FCLK.” However, after the rising edges of the rising clock “RCLK” and falling clock “FCLK” have been aligned, the second replica delay unit 130 is not used subsequent to the operation of the duty cycle compensation unit 160.

Therefore, a DLL apparatus constructed as shown in FIG. 1 includes a circuit (i.e., the second replica delay unit 130) that is unnecessary after a duty cycle compensation operation begins, thereby causing unnecessary current consumption.

In addition, in the DLL apparatus constructed as shown in FIG. 1, when an inputted external clock “CLK” has a short period “tCK” and a large duty error, the high pulse width of a clock sampled in the first and second phase detectors 120 and 140 may be too small for the first and second phase detectors 120 and 140 to correctly detect a phase difference.

When the first and second phase detectors 120 and 140 incorrectly detect a phase difference, the rising clock “PCLK” and falling clock “FCLK” may be incorrectly locked, or jitter may increase due to an error in phase detection despite the locked state of these clocks.

### SUMMARY OF THE INVENTION

Accordingly, the present invention has been made to solve the above and other problems occurring in the prior art. The present invention reduces errors generated by the phase difference detection in a DLL circuit through increasing the pulse widths of clocks used for the phase difference detection when the widths of the high pulses of the clocks are short.

In order to accomplish this, there is provided a delay-locked loop apparatus including: a rising-clock delay-locked circuit for detecting the phase difference between the first clock inputted as a reference clock and the second clock obtained by replica-delaying the first clock, delay-locking the first clock based on a result of the detection, and outputting the first clock as a rising clock; a falling-clock delay-locked circuit for detecting the phase difference between an inverted clock of the first clock and the rising clock after completion of a delay locking operation with respect to the rising clock, delay-locking the first clock based on the result of the detection, and outputting an inverted clock of the first clock as the falling clock; and a duty cycle compensation circuit for compensating duty cycles of the delay-locked rising clock and falling clock, wherein the falling-clock delay-locked circuit includes a divider for separately dividing the inverted clock and the delay-locked rising clock.

Preferably, the rising-clock delay-locked circuit includes: a replica delay unit for replica-delaying and outputting the first clock as the second clock; a first phase detector for detecting the phase difference between the first and second divided clocks and outputting the detected phase difference as the first detection signal; and a first delay locking unit for delay-locking the first clock by using the first detection signal, and outputting the first clock as the rising clock.

Preferably, the first delay locking unit includes: a first dual coarse delay line for receiving the first clock, dual-coarse-delaying the first clock according to the first detection signal, and outputting the dual-coarse-delayed first clock as first and second delayed clocks; and a first fine delay unit for receiving the first and second delayed clocks, fine-tuning the first and second delayed clocks according to the first detection signal, and outputting the first and second delayed clocks as the rising clock.

Preferably, the falling-clock delay-locked circuit includes: the divider for dividing and outputting the inverted clock of the first clock and the rising clock as first and second divided clocks, respectively; a second phase detector for detecting a phase difference between the first and second divided clocks and for outputting the detected phase difference as the second detection signal; and delay-locking the first clock by using the second detection signal, and inverting and outputting the delay-locked first clock as the falling clock.

Preferably, the divider includes: a first D flip-flop for receiving the inverted clock through the clock terminal of the first D flip-flop, in which an input terminal and an inverted output terminal of the first D flip-flop are connected to each other, and the first divided clock is outputted through an output terminal of the first D flip-flop; and a second D flip-flop for receiving the rising clock through the clock terminal of the second D flip-flop, in which an input terminal and an inverted output terminal of the second D flip-flop are connected to each other, and the second divided clock is outputted through an output terminal of the second D flip-flop.

Preferably, the second delay locking unit includes: a second dual coarse delay line for receiving the first clock, dual-coarse-delaying the first clock according to the second detection signal, and outputting the dual-coarse-delayed first clock as third and fourth delayed clocks; and a second fine delay unit for receiving the third and fourth delayed clocks, fine-tuning the third and fourth delayed clocks according to the second detection signal, and inverting and outputting the fine-tuned clock as the falling clock.

In accordance with another aspect of the present invention, there is provided a delay-locked loop apparatus that compensates for a discrepancy between the external clock and the internal clock or between the external clock and data when the external clock introduced from the exterior is used in a device, the delay-locked loop apparatus including: a phase detecting circuit for separately dividing the inverted clock of the external clock and the rising clock, which is delay-locked by using the external clock and a feedback clock obtained by replica-delaying the external clock, and detecting a phase difference between the divided clocks; a delay locking circuit for delay-locking the first clock based on a detection result of the phase detecting circuit, and outputting a falling clock aligned with the rising edge of the rising clock; and a duty cycle compensation circuit for compensating duty cycles of the delay-locked rising clock and falling clock.

Preferably, the phase detecting circuit includes: a divider for dividing and outputting the inverted clock and the rising clock as first and second divided clocks, respectively; and a phase detector for comparing the phases of the first and second divided clocks and for outputting a detection signal.

Preferably, the divider includes: a first D flip-flop for receiving the inverted clock through the clock terminal of the first D flip-flop, in which an input terminal and an inverted output terminal of the first D flip-flop are connected to each other, and the first divided clock is outputted through the output terminal of the first D flip-flop; and a second D flip-flop for receiving the rising clock through the clock terminal of the second D flip-flop, in which an input terminal and an inverted output terminal of the second D flip-flop are connected to each other, and the second divided clock is outputted through the output terminal of the second D flip-flop.

Preferably, the delay locking circuit includes: a dual coarse delay line for receiving the external clock, dual-coarse-delaying the external clock based on the detection result of the phase detecting circuit, and outputting the dual-coarse-delayed external clock as first and second delayed clocks; and a fine delay unit for receiving the first and second delayed clocks, fine-tuning the first and second delayed clocks based on the detection result of the phase detecting circuit, and inverting and outputting the first and second delayed clocks as the falling clock.

### BRIEF DESCRIPTION OF THE DRAWINGS

Various features and advantages of the present invention will be more apparent from the following detailed description taken in conjunction with the accompanying drawings, in which:

FIG. 1 is a block diagram illustrating the construction of a conventional delay-locked loop apparatus;

FIG. 2 is a block diagram illustrating the construction of a delay-locked loop apparatus according to an embodiment of the present invention;

FIG. 3 is a block diagram illustrating the operation of the first delay locking unit shown in FIG. 2; and

FIG. 4 is a circuit diagram illustrating the construction of the divider shown in FIG. 2.

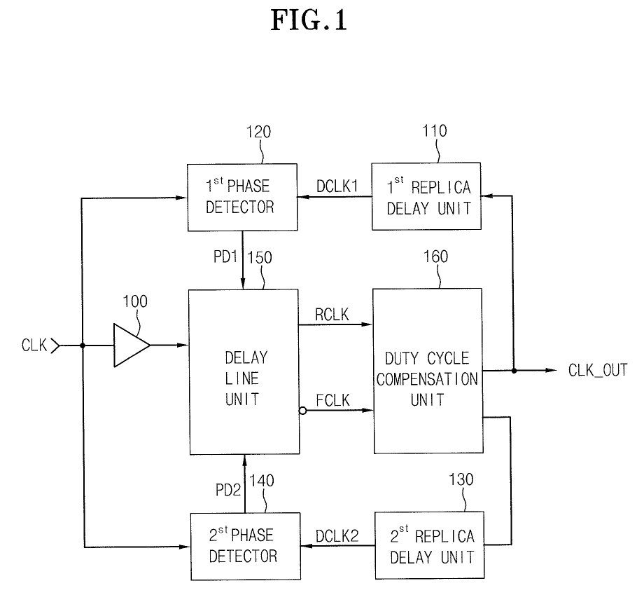

### DESCRIPTION OF SPECIFIC EMBODIMENTS

Hereinafter, a preferred embodiment of the present invention will be described with reference to the accompanying drawings. In the following description and drawings, the same reference numerals are used throughout to designate the same or similar components; therefore, repetition of the description of such same or similar components will be omitted.

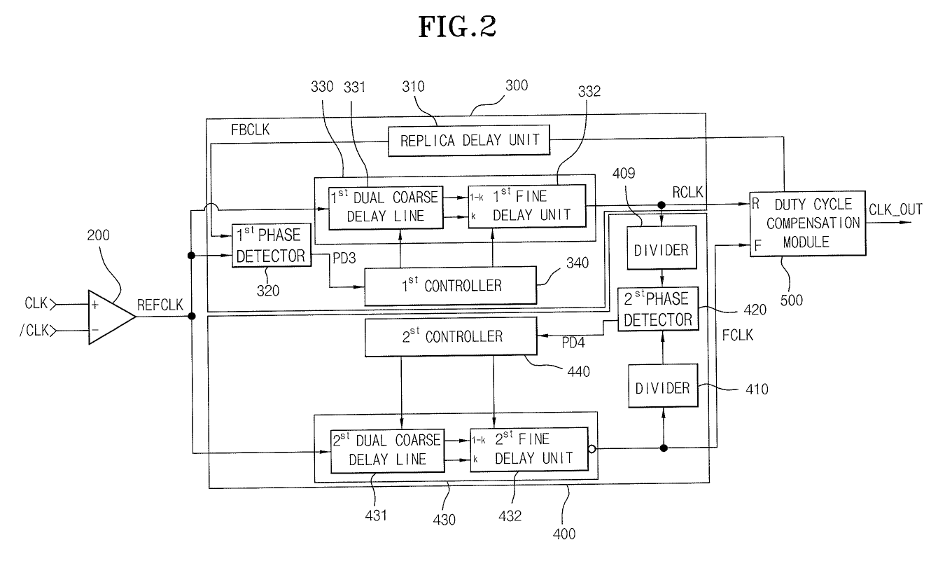

The construction of a delay-locked loop apparatus according to an embodiment of the present invention is shown in FIG. 2. It is noted that “clock signal” is also referred to as “clock” in this disclosure. According to an embodiment of the present invention, a reference clock “REFCLK” and a feedback clock “FBCLK” obtained by replica-delaying the reference clock “REFCLK” are compared to each other, and a delay locking operation for a rising clock “RCLK” is performed. Upon completion of the delay locking operation for the rising clock “RCLK,” an inverted clock obtained by inverting the reference clock “REFCLK” and the rising clock “RCLK” is divided to generate divided clocks “/DREFCLK_DIV” and “RCLK_DIV.” Then, the phases of the divided clocks “/DREFCLK_DIV” and “RCLK_DIV” are compared, and a delay locking operation is performed with respect to the falling clock “FCLK.”

In detail, the delay-locked loop apparatus shown in FIG. 2 according to an embodiment of the present invention includes a buffer module 200, a rising-clock delay-locked circuit 300, a falling-clock delay-locked circuit 400, and a duty cycle compensation module 500. The rising-clock delay-locked circuit 300 includes a replica delay unit 310, a first phase detector 320, a first delay locking unit 330, and a first controller 340. The falling-clock delay-locked circuit 400 includes a clock divider 410, a second phase detector 420, a second delay locking unit 430 and a second controller 440.

The buffer module 200 receives an external clock “CLK” and an inverted external clock “/CLK” through a non-inverting terminal and an inverting terminal, respectively, and outputs a reference clock “REFCLK.” After passing through the first delay locking unit 330 and duty cycle compensation module 500, the reference clock “REFCLK” is replica-delayed by the replica delay unit 310 and is outputted as a feedback clock “FBCLK.” In this case, the first delay locking unit 330 does not perform a delay locking operation, and the duty cycle compensation module 500 does not perform a duty cycle compensating operation.

The first phase detector 320 compares the phases of the reference clock “REFCLK” and feedback clock “FBCLK,” and outputs a detection signal “PD3.” The first controller 340 then receives the detection signal “PD3” and determines the degree of delay established in the first delay locking unit 330.

The first delay locking unit 330 delays the reference clock “REFCLK” by the amount of delay set by the first controller 340, and outputs the reference clock “REFCLK” as a rising clock “RCLK.” Herein, the first delay locking unit 330 may include a first dual coarse delay line 331 and a first fine delay unit 332.

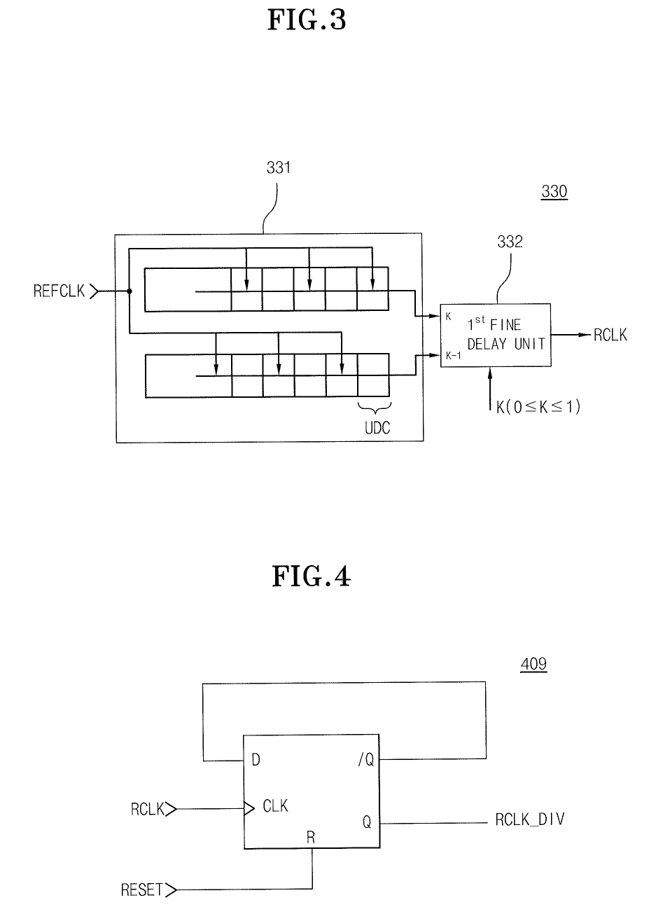

In detail, as shown in FIG. 3, the first dual coarse delay line 331 is constructed such that two coarse delay lines operate with a difference of one unit delay cell (UDC) therebetween, in which one coarse delay line uses an odd number of unit delay cells (UDCs) and the other coarse delay line uses an even number of unit delay cells (UDCs).

The first dual coarse delay line 331 delays the reference clock “REFCLK” by the amount of delay set by the first controller 340, and outputs two clocks having a difference of one unit delay cell (UDC) therebetween.

Thereafter, as shown in FIG. 3, the first fine delay unit 332 mixes (i.e., fine-tunes) the two clocks, which have been delayed by the first dual coarse delay line 331, based on weights (K) set by the first controller 340, thereby outputting the mixed signal as a delay-locked rising clock “RCLK.

When the delay locking operation for the rising clock signal “RCLK” has finished, the clock dividers 409, 410, the second phase detector 420 and the second delay locking unit 430 are activated to perform a delay locking operation with respect to the falling clock “FCLK.”

In detail, the reference clock “REFCLK” passes through the second delay locking unit 430 not performing a delay locking operation, and is outputted as an inverted clock. The inverted clock and the delay-locked rising clock “RCLK” are divided through the clock divider 410 and outputted as divided clocks “/DREFCLK_DIV” and “RCLK_DIV,” respectively.

Herein, the clock dividers 409, 410 may divide both the inverted clock and delay-locked rising clock “RCLK” by 1/n (herein, “n” is a natural number not less than “2”) using various circuits, such as a counter, a latch, and a flip-flop. For example, as shown in FIG. 4, the clock divider 409, 410 may divide an input clock by ½ by using a D flip-flop (hereinafter D-FF”).

That is, the D flip-flop “D-FF” is structured such that an input terminal “D” and an inverted output terminal “/Q” are connected to each other. The D flip-flop “D-FF” receives the inverted clock of the reference clock “REFCLK” (as in 410) or the rising clock “RCLK” (as in 409) through the clock terminal CLK, and outputs a divided clock “/DREFCLK_DIV” (as in 410) or divided clock “RCLK_DIV” (as in 409) through the output terminal Q. The D flip-flop “D-FF” receives a reset signal “RESET” through the reset terminal R and resets the dividing operation.

The second phase detector 420 compares the phases of the divided clocks “/DREFCLK_DIV” and “RCLK_DIV”, which were divided by the clock dividers 410, 409 respectively and outputs a detection signal “PD4.” The detection signal “PD4” is inputted to the second controller 440 and controls the degree of delay in the second delay locking unit 430.

The second delay locking unit 430 locks the delay of the reference clock “REFCLK” according to the amount of delay set by the second controller 440, inverts the locked clock, and then outputs the clock as a falling clock “FCLK.” Herein, similar to the first delay locking unit 330, the second delay locking unit 430 may include a second dual coarse delay line 431 and a second fine delay unit 432, which may be constructed in the same manner as that of the first delay locking unit 330; a detailed description thereof is therefore omitted.

Thereafter, the duty cycle compensation module 500 is activated when the rising edges of the rising clock “RCLK” and falling clock “FCLK” are aligned and locked, thereby mixing the two clocks “RCLK” and “FCLK,” and outputting an output clock “CLK_OUT,” the duty cycle of which has been compensated.

The operation of the DLL apparatus having the aforementioned construction according to an embodiment of the present invention will now be described in detail. First, the first phase detector 320 detects a phase difference between the reference clock “REFCLK” and the feedback clock “FBCLK” that have passed through the replica delay unit 310, thereby starting the delay locking operation with respect to the rising clock “RCLK.”

Herein, according to an embodiment of the present invention, it is possible to individually divide the reference clock “REFCLK” and feedback clock “FBCLK” as shown in FIG. 4 and to detect the phase difference between the two divided clocks.

Then, upon completion of the coarse locking operation through the first dual coarse delay line 331, a fine tuning operation starts through the first fine delay unit 332. When a phase difference between the reference clock “REFCLK” and feedback clock “FBCLK” enters the range of one fine unit delay, the clock divider 410, the second phase detector 420 and the second delay locking unit 430 begin to operate.

In this case, from the point at which the clock divider 410, the second phase detector 420 and the second delay locking unit 430 start to operate to the point at which the duty cycle compensation operation starts, the rising clock “RCLK” is maintained in a locked state.

Thereafter, a duty cycle compensation operation begins when the phase difference between the clocks “/DREFCLK_DIV” and “RCLK_DIV” divided by the clock divider 410 goes into the range of one fine unit delay, that is, when the rising edge of the falling clock “FCLK” is aligned with the rising edge of the rising clock “RCLK.”

As described above, according to an embodiment of the present invention, a single replica delay unit can compensate for a discrepancy between an external clock and data or between an external clock and an internal clock, thereby reducing unnecessary current consumption, as compared with the conventional DLL apparatus employing two replica delay units.

In addition, according to an embodiment of the present invention, when the period of an external clock “CLK” is short and the duty error is large, an input clock, that is, a reference clock “REFCLK” and a feedback clock “FBCLK,” or an inverted clock of the reference clock “REFCLK” and a rising clock “RCLK,” is divided, thereby securing a high pulse wide enough to detect the phase difference, and reducing the jitter component generated by the phase difference detection error.

Therefore, according to the present invention, the delay locking operation is performed by using a single replica delay unit, thereby reducing unnecessary current consumption, as compared with the conventional DLL apparatus employing two replica delay units.

In addition, according to the present invention, a phase difference is detected by dividing the reference clock and the feedback clock, or by dividing a clock inverted from the reference clock and the rising clock “RCLK,” thereby reducing the jitter component generated by the phase difference detection error.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A delay-locked loop apparatus comprising:
a rising-clock delay-locked circuit for detecting the phase difference between a first clock inputted as a reference clock and a second clock obtained by replica-delaying the first clock, delay-locking the first clock based on a result of the detection, and outputting the first clock as a rising clock;
a falling-clock delay-locked circuit for detecting the phase difference between an inverted clock of the first clock and the rising clock after a delay locking operation with respect to the rising clock is completed, delay-locking the first clock based on the result of the detection, and outputting an inverted clock of the first clock as a falling clock; and
a duty cycle compensation circuit for compensating duty cycles of the delay-locked rising clock and falling clock,
wherein the falling-clock delay-locked circuit comprises a divider for separately dividing the inverted clock and the delay-locked rising clock.

2. The delay-locked loop apparatus as claimed in claim 1, wherein the rising-clock delay-locked circuit comprises:
a replica delay unit for replica-delaying the first clock and outputting the replica-delayed first clock as the second clock;
a first phase detector for detecting the phase difference between first and second clocks and outputting the detected phase difference as a first detection signal; and
a first delay locking unit for delay-locking the first clock by using the first detection signal, and outputting the first clock as the rising clock.

3. The delay-locked loop apparatus as claimed in claim 2, wherein the first delay locking unit comprises:
a first dual coarse delay line for receiving the first clock, dual-coarse-delaying the first clock according to the first detection signal, and outputting the dual-coarse-delayed first clock as first and second delayed clocks; and
a first fine delay unit for receiving the first and second delayed clocks, fine-tuning the first and second delayed clocks according to the first detection signal, and outputting the first and second delayed clocks as the rising clock.

4. The delay-locked loop apparatus as claimed in claim 1, wherein the divider of the falling-clock delay-locked circuit divides and outputs the inverted clock of the first clock and the rising clock as first and second divided clocks, respectively, and wherein the falling-clock delay-locked circuit further comprises:
a second phase detector for detecting the phase difference between the first and second divided clocks and for outputting the detected phase difference as a second detection signal; and
a second delay-locking unit for delay-locking the first clock by using the second detection signal, and inverting and outputting the delay-locked first clock as the falling clock.

5. The delay-locked loop apparatus as claimed in claim 4, wherein the divider comprises:
a first D flip-flop having a clock terminal, an input terminal, an inverted output terminal, and an output terminal, the first D flip-flop, wherein the inverted clock is received through the clock terminal of the first D flip-flop, the input terminal and the inverted output terminal of the first D flip-flop are connected to each other, and the first divided clock is outputted through the output terminal of the first D flip-flop; and
a second D flip-flop having a clock terminal, an input terminal, an inverted output terminal, and an output terminal, the second D flip-flop, wherein the rising clock is received through the clock terminal of the second D flip-flop, an input terminal and an inverted output terminal of the second D flip-flop are connected to each other, and the second divided clock is outputted through the output terminal of the second D flip-flop.

6. The delay-locked loop apparatus as claimed in claim 4, wherein the second delay locking unit comprises:
a second dual coarse delay line for receiving the first clock, dual-coarse-delaying the first clock according to the second detection signal, and outputting the dual-coarse-delayed first clock as third and fourth delayed clocks; and
a second fine delay unit for receiving the third and fourth delayed clocks, fine-tuning the third and fourth delayed clocks according to the second detection signal, and inverting and outputting the fine-tuned clock as the falling clock.

7. A delay-locked loop apparatus for compensating for a skew between an external clock and an internal clock generated from the external clock or between the external clock and a signal carrying data when the external clock introduced from outside the delay-locked loop apparatus is used in a device, the delay-locked loop apparatus comprising:
a phase detecting circuit for separately dividing an inverted clock of the external clock and a rising clock, which is delay-locked by using the external clock and a feedback clock obtained by replica-delaying the external clock, and detecting the phase difference between the divided clocks;
a delay locking circuit for delay-locking the first clock based on the detection results of the phase detecting circuit, and outputting a falling clock aligned with the rising edge of the rising clock; and
a duty cycle compensation circuit for compensating duty cycles of the delay-locked rising clock and falling clock.

8. The delay-locked loop apparatus as claimed in claim 7, wherein the phase detecting circuit comprises:
a divider for dividing and outputting the inverted clock and the rising clock as first and second divided clocks, respectively; and
a phase detector for comparing the phases of the first and second divided clocks and for outputting a detection signal.

9. The delay-locked loop apparatus as claimed in claim 8, wherein the divider comprises:
a first D flip-flop having a clock terminal, an input terminal, an inverted output terminal, and an output terminal, wherein the inverted clock is received through the clock terminal of the first D flip-flop, the input terminal and the inverted output terminal of the first D flip-flop are connected to each other, and the first divided clock is outputted through the output terminal of the first D flip-flop; and
a second D flip-flop having a clock terminal, an input terminal, an inverted output terminal, and an output terminal, wherein the rising clock is received through the clock terminal of the second D flip-flop, the input terminal and the inverted output terminal of the second D flip-flop are connected to each other, and the second divided clock is outputted through the output terminal of the second D flip-flop.

10. The delay-locked loop apparatus as claimed in claim 7, wherein the delay locking circuit comprises:
a dual coarse delay line for receiving the external clock, dual-coarse-delaying the external clock based on the detection result of the phase detecting circuit, and outputting the dual-coarse-delayed external clock as first and second delayed clocks; and
a fine delay unit for receiving the first and second delayed clocks, fine-tuning the first and second delayed clocks based on the detection results of the phase detecting circuit, and inverting and outputting the first and second delayed clocks as the falling clock.
